(19) United States
(12) Patent Application Publication
(10) Pub. No.: US 2025/0246463 A1
(43) Pub. Date: Jul. 31, 2025

(54) ANALYSIS METHOD AND ANALYSIS DEVICE FOR SEMICONDUCTOR MANUFACTURING PROCESS

(71) Applicant: United Microelectronics Corp, Hsinchu (TW)

(72) Inventors: Chuang-Tse WANG, Hsinchu City (TW); Kuang-Hsien TSENG, Hsinchu City (TW); Chun-Kai CHAN, Kaohsiung City (TW); Chen-Chuan YU, Hsinchu City (TW); Po-Sheng LEE, Hsinchu County (TW)

(21) Appl. No.: 18/600,806

(22) Filed: Mar. 11, 2024

(30) Foreign Application Priority Data
Jan. 31, 2024 (CN) 202410137436.9

(51) Int. Cl. H01L 21/67; G05B 19/418; H01L 21/66

(52) U.S. Cl. CPC H01L 21/67276; G05B 19/41865; G05B 19/4189; H01L 22/20; G05B 2219/45031

(57) ABSTRACT

An analysis method and an analysis device for a semiconductor manufacturing process are provided. The analysis method of the semiconductor manufacturing process includes the following steps. A semiconductor machine log file is loaded. A plurality of machine action events are defined from the semiconductor manufacturing machine log file. A wafer moving path map is generated according to a wafer moving information file. A plurality of account point information are bound to each of the machine action events according to the wafer moving path map. A wafer movement tracking graph is generated according to the machine action events that have been bound to account information.

This application claims the benefit of China application Serial No. 202410137436.9, filed Jan. 31, 2024, the subject matter of which is incorporated herein by reference.

### BACKGROUND OF THE INVENTION

### Field of the Invention

The invention relates in general to an analysis method and an analysis device of a manufacturing process, and more particularly to an analysis method and an analysis device for a semiconductor manufacturing process.

### Description of the Related Art

During the process of constructing the industry 4.0 big data system, data pre-processing amounts to 70 to 80% of the work. For instance, the machine log file records the execution time of each action performed at various sites by the wafers of several lots of the machine. To analyze the wait time waste of a manufacturing process for the purpose of optimization of manufacturing process, the machine log file needs a series of pre-processing treatments before the time string of a plurality of actions of a wafer in the machine can be obtained. Since the format and content of log file may vary with the machine, the pre-processing treatment for each machine log file may take up to 2 to 3 months in the development of Parser program. These factors often make projects of manufacturing process optimization unable to go smoothly.

### SUMMARY OF THE INVENTION

The invention is directed to an analysis method and an analysis device for a semiconductor manufacturing process, which dispenses with Parser development through the use of graphics processing technology. Without writing any Parser programs, the analyst can complete the analysis of semiconductor manufacturing process through a graphics interface.

According to one embodiment of the present invention, an analysis method of a semiconductor manufacturing process is provided. The analysis method of a semiconductor manufacturing process includes the following steps. A semiconductor machine log file is loaded. A plurality of machine action events are defined from the semiconductor manufacturing machine log file. A wafer moving path map is generated according to a wafer moving information file. A plurality of account point information are bound to each of the machine action events according to the wafer moving path map. A wafer movement tracking graph is generated according to the machine action events that have been bound to account information.

According to another embodiment of the present invention, an analysis device of a semiconductor manufacturing process is provided. The analysis device of a semiconductor manufacturing process includes a read unit, an action definition unit, a movement information graphics unit, a binding unit and a tracking information graphics unit. The read unit is configured to load a semiconductor machine log file. The action definition unit is configured to provide an operation interface to define a plurality of machine action events from the semiconductor manufacturing machine log file. The movement information graphics unit is configured to generate a wafer moving path map according to a wafer moving information file. The binding unit is configured to bind a plurality of account point information to each of the machine action events according to the wafer moving path map. The tracking information graphics unit is configured to generate a wafer movement tracking graph according to the machine action events that have been bound to account information.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 is a schematic diagram of an analysis method of a semiconductor manufacturing process according to an embodiment of the present disclosure.

FIG. 2 is a schematic diagram of an analysis device of a semiconductor manufacturing process according to an embodiment of the present disclosure.

FIG. 3 is a flowchart of an analysis method of a semiconductor manufacturing process according to an embodiment.

FIG. 4 illustrates step S110.

FIG. 5 illustrates an operation interface according to an embodiment of the present disclosure.

FIG. 6 illustrates a wafer moving path map according to an embodiment of the present disclosure.

FIG. 7 illustrates a wafer movement tracking graph according to an embodiment of the present disclosure.

### DETAILED DESCRIPTION OF THE INVENTION

Technical terms are used in the specification with reference to the prior art used in the technology field. For any terms described or defined in the specification, the descriptions and definitions in the specification shall prevail. Each embodiment of the present disclosure has one or more technical features. Given that each embodiment is implementable, a person ordinarily skilled in the art can selectively implement or combine some or all of the technical features of any embodiment of the present disclosure.

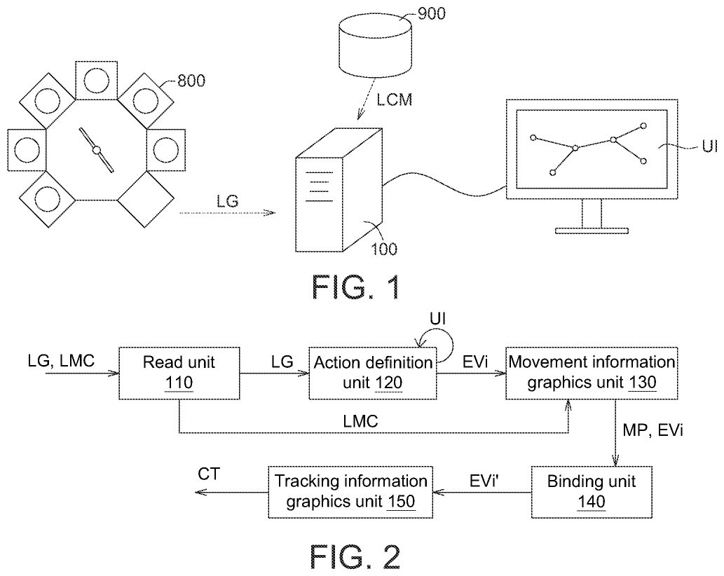

Referring to FIG. 1, a schematic diagram of an analysis method of a semiconductor manufacturing process according to an embodiment of the present disclosure is shown. In the present embodiment, the analysis device 100 of a semiconductor manufacturing process automatically obtains a semiconductor machine log file LG and a wafer moving information file LMC from the semiconductor machine 800 and the database 900 at the backstage, then performs analysis and binding. With a simple operation on the operation interface UI, the user can complete the analysis of semiconductor manufacturing process. For instance, suppose the analysis of wait time waste in the manufacturing process is needed. With the technology of the present disclosure, the user despite being a programming illiterate could successfully obtain the bottlenecks and improvement opportunities of machine operations within a few hours, and accordingly perform manufacturing process optimization.

Referring to FIG. 2, an analysis device 100 of a semiconductor manufacturing process according to an embodiment of the present disclosure is shown. The analysis device 100 includes a read unit 110, an action definition unit 120, a movement information graphics unit 130, a binding unit 140 and a tracking information graphics unit 150. The read unit 110 is configured to read data and could be realized by such as a wireless network transmission unit, a wired network transmission unit or a transmission line.

The action definition unit 120, the movement information graphics unit 130, the binding unit 140 and the tracking information graphics unit 150 are configured to execute various data and graphics processing procedures. The action definition unit 120, the movement information graphics unit 130, the binding unit 140 and/or the tracking information graphics unit 150 could be realized by such as a circuit, a circuit board, a storage device storing programming code, or a chip. The chip could be realized by such as a central processing unit (CPU), a programmable general purpose or specific purpose micro control unit (MCU), a microprocessor, a digital signal processor (DSP), a programmable controller, an application specific integrated circuit (ASIC), a graphics processing unit (GPU), an image signal processor (ISP), an image processing unit (IPU), an arithmetic logic unit (ALU), a complex programmable logic device (CPLD), a field programmable gate array (FPGA), other similar element or a combination thereof.

In the present disclosure, after the read unit 110 automatically obtains the semiconductor machine log file LG and the wafer moving information file LMC from the semiconductor machine 800 and the database 900 at the backstage, the action definition unit 120, the movement information graphics unit 130, the binding unit 140 and the tracking information graphics unit 150 then perform analysis and binding on the semiconductor machine log file LG and the wafer moving information file LMC. With a simple operation on the operation interface UI, the user could complete the analysis of semiconductor manufacturing process. The operation of the above elements is disclosed below with an accompanying flowchart.

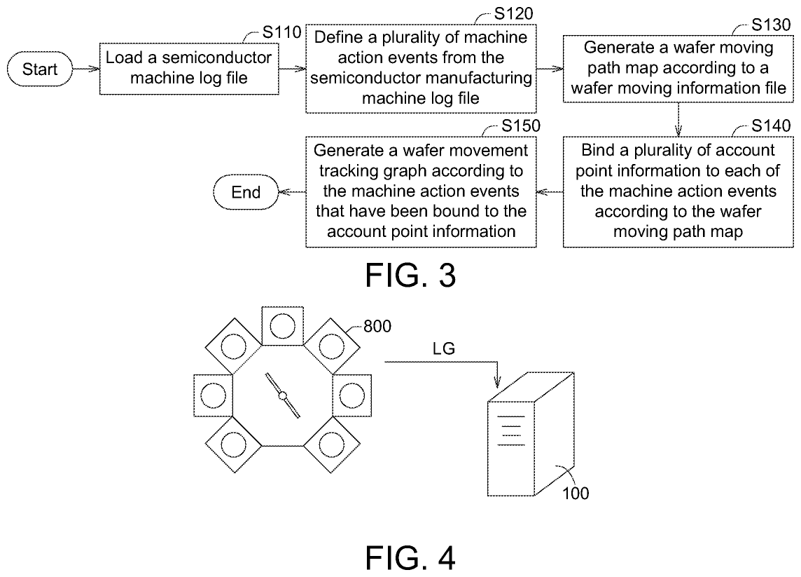

Referring to FIG. 3, a flowchart of an analysis method of a semiconductor manufacturing process according to an embodiment is shown. The analysis method of the semiconductor manufacturing process includes step S110 to S150. In the step S110, the semiconductor machine log file LG is loaded by the read unit 110. Referring to FIG. 4, the step S110 is illustrated. Normally the semiconductor machine 800 consecutively processes several wafers of several lots. The semiconductor machine 800 normally has several chambers, and the robotic arm controls the wafers to be received at a cartridge, a chamber or various sites in the transportation space. Thus, the semiconductor machine log file LG normally contains the time information of several lots, wafers, actions and sites. It is difficult to directly analyze the bottlenecks and improvement opportunities of the semiconductor manufacturing process from the complicated semiconductor machine log file LG.

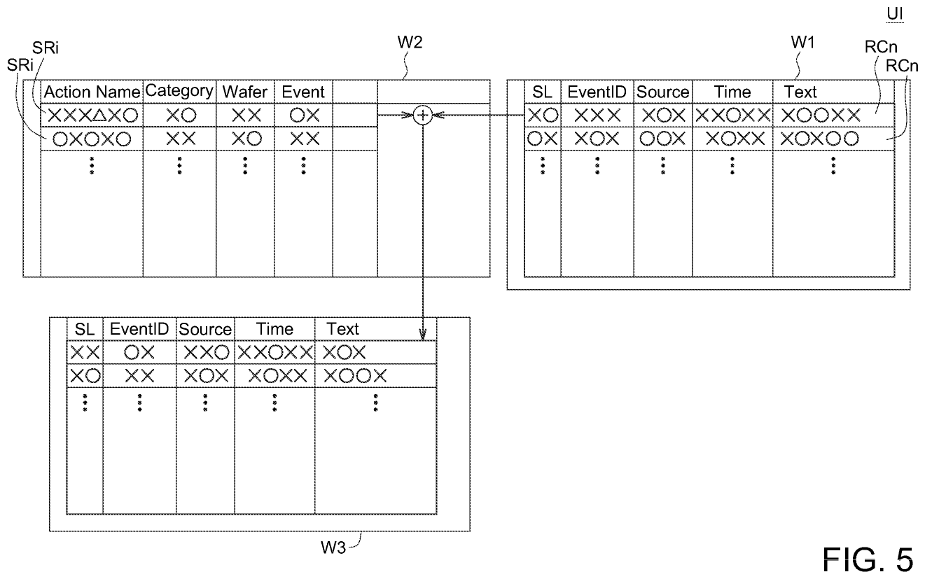

Next, the method proceeds to step S120. An operation interface U1 is provided by the action definition unit 120 to define a plurality of machine action events Evi from the semiconductor manufacturing machine log file LG. Referring to FIG. 5, an operation interface U1 according to an embodiment of the present disclosure is shown. The operation interface U1 exemplarily includes an original record window W1, a condition window W2 and an event window W3. The original record window W1 is configured to display a semiconductor machine log file LG. The semiconductor machine log file LG may contain thousands of semiconductor machine records RCn. Although the semiconductor machine records RCn contain time information, it is difficult to analyze the bottlenecks and improvement opportunities of the semiconductor manufacturing process directly from the semiconductor machine records RCn because the semiconductor machine records RCn correspond to several lots, wafers, actions and sites.

The condition window W2 is configured to set at least one search condition SRi. The user could set a search condition Sri on the condition window W2 through typing or menu selection. Or, in another embodiment, the search condition Sri could be automatically set using Al technology.

After the user clicks a search condition SRi on the condition window W2, the event window W3 will display a machine action event EVi corresponding to the search condition SRi.

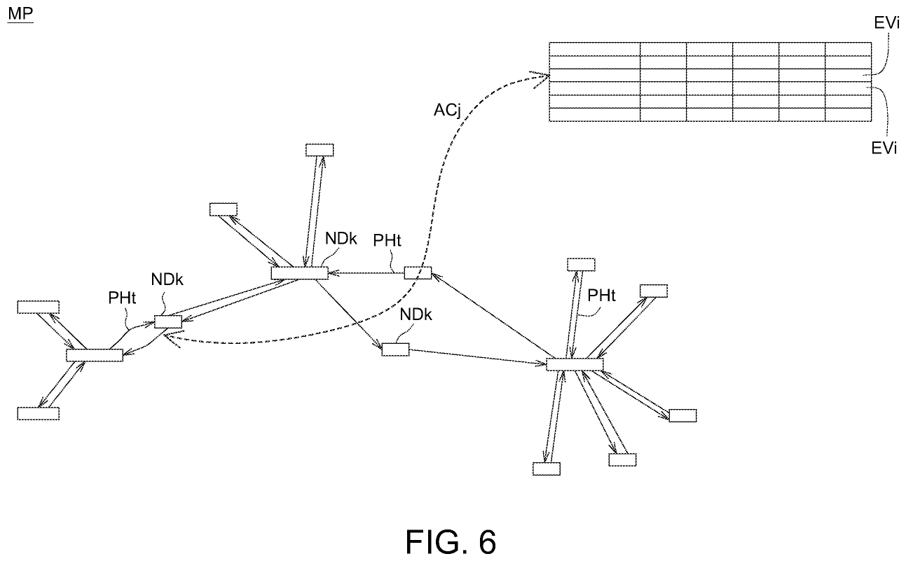

Then, the method proceeds to the step S130, a wafer moving path map MP is generated by the movement information graphics unit 130 according to the wafer moving information file LMC. Referring to FIG. 6, a wafer moving path map MP according to an embodiment of the present disclosure is illustrated. The wafer moving path map MP could correspond to one wafer or several wafers. The wafer moving path map MP includes a plurality of mechanism nodes NDk and a plurality of paths PHt connecting the mechanism nodes NDk. The mechanism nodes NDk could be realized by such as a wafer halt point or structural unit of the semiconductor machine 800. As indicated in FIG. 6, the wafer moving path map MP is a closed path graph.

Then, the method proceeds to the step S140, a plurality of account point information ACj are bound to each of the machine action events Evi by the binding unit 140 according to the wafer moving path map MP. The account point information ACj includes a lot information (LotID), a program name (PPID), a chamber information (ChID), a chamber program information (ChPPID), a site information (Site) and a step information (StepNo.). The account point information ACj contained in the wafer moving information file LMC are more complete than that contained in the semiconductor machine log file LG. Through the correspondence of the wafer moving path map MP, the account point information ACj could be successfully bound to each of the machine action events EVi.

As indicated in FIG. 6, the wafer moving path map MP has the advantage of graphics. When the user direct clicks a path PHt on the wafer moving path map MP, the machine action event Evi corresponding to the clicked path will be immediately displayed.

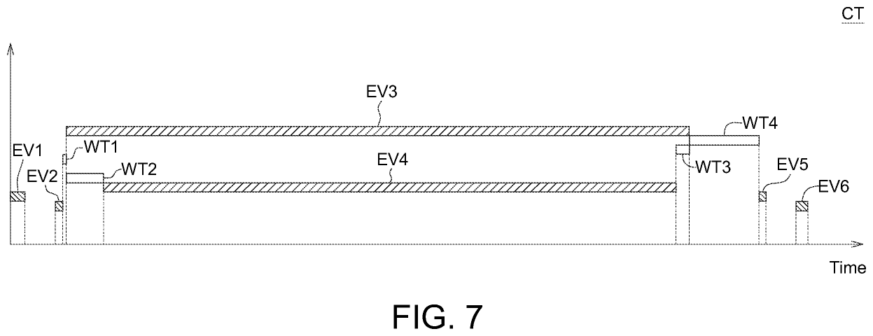

Then, the method proceeds to the step S150, a wafer movement tracking graph CT is generated by the tracking information graphics unit 150 according to the machine action event EVi′ that have been bound to the account point information ACj. Referring to FIG. 7, a wafer movement tracking graph CT according to an embodiment of the present disclosure is illustrated. On the wafer movement tracking graph CT, the start/finish time of each of the action events EVi′ is illustrated in a Gant chart. For instance, the user selects the action event EV3 corresponding to “chamber operation” and the action event EV4 3 corresponding to “recipe formation”. Then, the user could again select the action events EV1, EV2, EV5, EV6 corresponding to “robotic arm operation”. The Gant chart of the action events EV1 to EV6 clearly shows that the action event EV2 corresponding to “robotic arm operation” does not immediately precede the action event EV3 corresponding to “chamber operation” or the action event EV4 corresponding to “recipe formation”; rather, the action event EV2 precedes the action event EV3 by a critical wait time WT1 and precedes the action event EV4 by the critical wait time WT1 and a critical wait time WT2. The action event EV3 corresponding to “chamber operation” or the action event EV4 corresponding to “recipe formation” does not immediately precede the action event EV5 corresponding to “robotic arm operation”; rather, the action event EV3 precedes the action event EV5 by a critical wait time WT4 and the action event EV4 precedes the action event EV5 by a critical wait time WT3 and the critical wait time WT4. The critical wait times WT1 to WT4 optimize the bottlenecks and improvement opportunities of the semiconductor manufacturing process.

In another embodiment, a comparison between the action event EVi could be performed by using the wafer movement tracking graph CT to analyze the critical time-consuming action.

Through the analysis method and the device analysis device 100 of the semiconductor manufacturing process disclosed in the above embodiments, the analysis device 100, after automatically obtaining the semiconductor machine log file LG and the wafer moving information file LMC from the semiconductor machine 800 and the database 900 at the backstage, could perform data analysis, binding and graphics to the semiconductor machine log file LG and the wafer moving information file LMC. With a simple operation on the graphics interface, the user could complete the analysis of semiconductor manufacturing process. With the technology of the present disclosure, the user despite being a programming illiterate can successfully obtain the bottlenecks and improvement opportunities of machine operations within a few hours, and accordingly perform manufacturing process optimization.

The above disclosure provides distinctive features of some implementations or examples. Some implementations of the present disclosure are simplified or schematically illustrated through specific examples (such as numeric values or names) regarding the elements and arrangement of the device. However, these specific examples are not for limiting the present disclosure. Besides, in some implementations of the present disclosure, reference designations and/or alphabets can be repeated. Such repetitions are for the purpose of simplification and clarification, not for specifying the relationship between the embodiments and/or configurations.

While the invention has been described by way of example and in terms of the preferred embodiment(s), it is to be understood that the invention is not limited thereto. Based on the technical features embodiments of the present invention, a person ordinarily skilled in the art will be able to make various modifications and similar arrangements and procedures without breaching the spirit and scope of protection of the invention. Therefore, the scope of protection of the present invention should be accorded with what is defined in the appended claims.

What is claimed is:

1. An analysis method of a semiconductor manufacturing process, comprising:
loading a semiconductor machine log file;
defining a plurality of machine action events from the semiconductor manufacturing machine log file;
generating a wafer moving path map according to a wafer moving information file;
binding a plurality of account point information to each of the machine action events according to the wafer moving path map; and
generating a wafer movement tracking graph according to the machine action events that have been bound to the account point information.

2. The analysis method of the semiconductor manufacturing process according to claim 1, wherein in the step of defining the machine action events, an operation interface comprises an original record window, a condition window and an event window; the original record window is configured to display the semiconductor machine log file, the condition window is configured to set at least one search condition, and the event window is configured to display the machine action events.

3. The analysis method of the semiconductor manufacturing process according to claim 1, wherein the wafer moving path map comprises a plurality of mechanism nodes and a plurality of paths connecting the mechanism nodes.

4. The analysis method of the semiconductor manufacturing process according to claim 3, wherein the wafer moving path map is a closed path graph.

5. The analysis method of the semiconductor manufacturing process according to claim 1, wherein the account point information comprises a lot information, a program name, a chamber information, a chamber program information, a site information and a step information.

6. The analysis method of the semiconductor manufacturing process according to claim 1, wherein the wafer movement tracking graph corresponds to a wafer.

7. The analysis method of the semiconductor manufacturing process according to claim 1, wherein the wafer movement tracking graph corresponds to a plurality of wafers.

8. The analysis method of the semiconductor manufacturing process according to claim 1, wherein the wafer movement tracking graph is configured to analyze a critical wait time.

9. The analysis method of the semiconductor manufacturing process according to claim 1, wherein the wafer movement tracking graph is configured to analyze a critical time-consuming action.

10. An analysis device of a semiconductor manufacturing process, comprises:
a read unit, configured to load a semiconductor machine log file;
an action definition unit, configured to provide an operation interface to define a plurality of machine action events from the semiconductor manufacturing machine log file;
a movement information graphics unit, configured to generate a wafer moving path map according to a wafer moving information file;
a binding unit, configured to bind a plurality of account point information to the machine action events according to the wafer moving path map; and
a tracking information graphics unit, configured to generate a wafer movement tracking graph according to the machine action events that have been bound to the account point information.

11. The analysis device of the semiconductor manufacturing process according to claim 10, wherein the operation interface comprises an original record window, a condition window and an event window; the original record window is configured to display the semiconductor machine log file, the condition window is configured to set at least one search condition, and the event window is configured to display the machine action events.

12. The analysis device of the semiconductor manufacturing process according to claim 10, wherein the wafer moving path map comprises a plurality of mechanism nodes and a plurality of paths connecting the mechanism nodes.

13. The analysis device of the semiconductor manufacturing process according to claim 12, wherein the wafer moving path map is a closed path graph.

14. The analysis device of the semiconductor manufacturing process according to claim 10, wherein the account point information comprises a lot information, a program name, a chamber information, a chamber program information, a site information and a step information.

15. The analysis device of the semiconductor manufacturing process according to claim 10, wherein the wafer movement tracking graph corresponds to a wafer.

16. The analysis device of the semiconductor manufacturing process according to claim 10, wherein the wafer movement tracking graph corresponds to a plurality of wafers.

17. The analysis device of the semiconductor manufacturing process according to claim 10, wherein the wafer movement tracking graph is configured to analyze critical wait time.

18. The analysis device of the semiconductor manufacturing process according to claim 10, wherein the wafer movement tracking graph is configured to analyze a critical time-consuming action.
